(19) United States
(12) Patent Application Publication
(10) Pub. No.: US 2003/0000076 A1
(43) Pub. Date: Jan. 2, 2003

(54) Insertion head comprising a rotational device for electric components

(76) Inventors: Wolfgang Huber, Munchen (DE); Mohammad Mehdianpour, Munchen (DE); Ralf Schulz, Munchen (DE)

Correspondence Address: HARNESS, DICKEY & PIERCE, P.L.C., P.O.BOX 8910, RESTON, VA, 20195, US

(21) Appl. No.: 10/168,493

(22) PCT Filed: Dec. 20, 2000
(86) PCT No.: PCT/DE00/04576

(30) Foreign Application Priority Data
Dec. 21, 1999 (DE) 19961778.3

(51) Int. Cl. B23P 19/00; H05K 3/30

(52) U.S. Cl. 29/739; 29/834

(57) ABSTRACT

Arranged along a path of movement of a gripper are friction blocks on which a slewing ring of the gripper rolls, whereby the gripper with the component is rotated. This allows the component to be rotated into its approximate placement position in a time-saving manner before the position is measured, during the forward movement of the gripper.

The invention relates to an insertion head comprising at least one rotational device for electric components, the turret-like insertion head having a stator and a rotor, on [lacuna] a multiplicity of circularly distributed grippers are mounted independently rotatably about a placement axis, the insertion head having an optical measuring device for detecting the position of the components held on the grippers and it being possible after the optical measurement for the components to be rotated by a fine rotational device precisely into the required placement position.

It is known from EP-C 0 315 799 to provide an insertion device with a movable turret head, in which the grippers provided with suction pipettes are arranged protruding in a star-shaped manner on a rotor. A stator of the insertion head is provided with peripherally distributed processing stations.

It is customary to design one of these stations as an optical measuring station, in which the rotational position of the previously received component is ascertained. In a following rotational station, the position of the component is changed in a way corresponding to the desired installation position. This change comprises a coarse rotation, for example in steps of 45°, corresponding to the desired installation position and a fine rotation, which compensates for the picking inaccuracy when the components are received from a feeding device.

It is also customary to provide the gripper with a disk-like slewing ring of relatively large diameter. On this, a friction wheel of the rotational device can be radially mounted, whereupon the rotational device is activated and brings about a precise rotation of the gripper by a precalculated angle. Since the components are to be placed onto the printed circuit board in different installation positions, the angle of rotation can be so large that the entire rotational cycle lasts longer than the operating cycles at other stations of the turret head, as a result of which the insertion capacity of the latter is correspondingly limited.

The invention is based on the object of reducing the time loss when the grippers are rotated.

This object is achieved by the invention as claimed in claim 1. The rotation of the gripper is now divided into two stages, the coarse rotation taking place rapidly, without being especially accurate, in a rotor segment before [lacuna] optical measuring device. Even in the case of a large overall angle of rotation, this allows the angle of rotation in the fine rotational device to be shortened to such an extent that the fine adjustment does not taken longer than, for example, than the optical measurement in the measuring device.

Advantageous developments of the invention are characterized in the subclaims.

The development as claimed in claim 2 has the effect that the measurement and fine rotation of the components take place at a standstill. The measuring station and fine rotational station as well as the coarse rotational station as claimed in claim 3 are fastened in a simple way on the stator and can enter into a precise operative connection with the component or with the gripper.

The frictional surface as claimed in claim 4 has the effect that the coarse rotation takes place during the in any case required forward movement of the gripper, without any time loss. The stationary frictional surface may be formed on a simple structural part, on which the slewing ring keeps rolling until the desired end position is at least approximately reached. The length of engagement between the frictional surface and the slewing ring can be accurately terminated by a radial infeed movement of the rotational device, for example with the aid of piezoelectric drive elements of short response time, so that the gripper can be rotated by the calculated angle.

The development as claimed in claim 5 makes it possible to carry out the coarse rotation with little control effort.

The friction block as claimed in claim 6 represents a simple, easy-to-actuate component.

The development as claimed in claim 7 makes it possible to form the length of the frictional surfaces such that an angle of rotation of, for example, 45° is respectively achieved at the gripper. It is possible for the angle of rotation to be multiplied by providing a corresponding number of the friction blocks, adjusted in a switchable manner into the path of movement of the slewing ring.

The development as claimed in claim 8 ensures that the grippers can be moved with the slewing rings along a precisely defined path. For example, in the case of a star-shaped turret head with radially protruding grippers, the slewing rings move within a plane, so that the friction blocks can also be arranged in a plane, which is accompanied by assembly advantages. The shortening of the friction blocks ensures that each frictional surface is respectively covered only by one slewing ring. This allows them to be rotated differently and individually in accordance with the specified requirement.

The invention is explained in more detail below on the basis of an exemplary embodiment represented in the drawing.

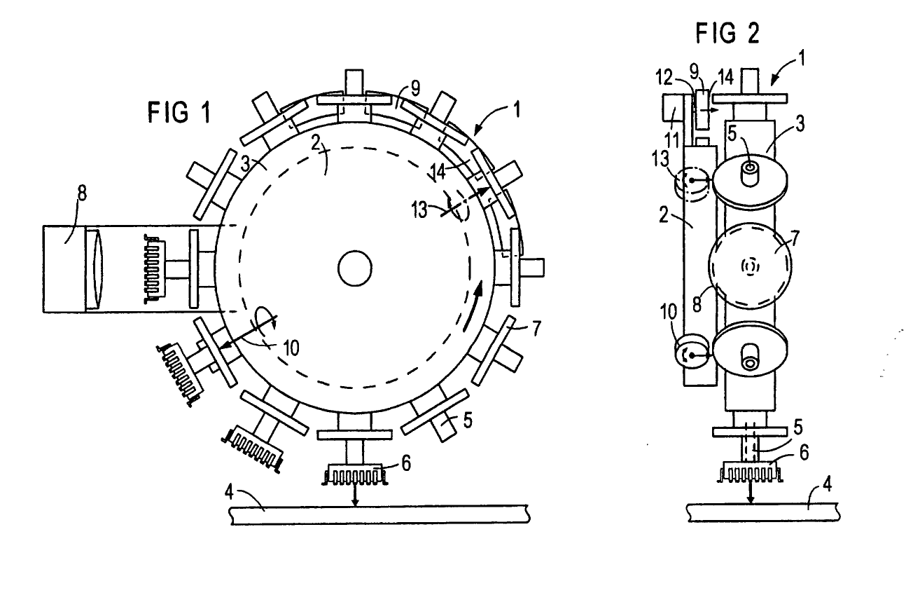

FIG. 1 shows a side view of an insertion head for inserting components into electrical printed circuit boards,

FIG. 2 shows another side view of the insertion head as shown in FIG. 1.

As shown in FIGS. 1 and 2, a turret-head-like insertion head 1 comprises a stator 2 and a rotor 3. The insertion head can be moved over a printed circuit board 4 and has grippers 5 protruding radially in a star-shaped manner, which are provided with suction pipettes, on the free ends of which electric components 6 are held. The rotor can be rotated step by step by an index angle, which corresponds to the pitch angle of the grippers 5. The grippers 5 can be pushed out telescopically from the rotor. The gripper 5 that is respectively in the placement position can consequently place the component 6 onto the printed circuit board 4 in the perpendicular direction of the arrow represented.

The rotatably mounted grippers 5 are provided with slewing rings 7 formed in the manner of disks. An optical measuring station 8 serves for measuring the position of the components 6 with respect to the gripper 5. Fitted on the stator 2 along the path of movement of the slewing rings 7 are friction blocks 9, which can be deflected in the horizontal direction of the arrow to the extent that their frictional surfaces 14 can be placed onto the slewing rings 7. When the rotor 3 is rotated, the slewing rings 7 consequently roll with their lateral surfaces on the frictional surfaces 14 and are correspondingly rotated. This rotation takes place in a time-saving manner between the holding stations of the rotor 3. The length of the friction blocks 9 is dimensioned such that the grippers 5 are respectively rotated by, for example, 45°.

By switching the brake block infeed on and off, the gripper can be rotated by a desired multiple of the coarse angle of rotation. Following this coarse rotation, the components 6 are measured in the optical station and their deviation from the installation position is determined. A following fine rotational device 10 is assigned to one of the holding stations. In it, the rotational position of the gripper 5 can be changed in fine stages and the desired installation position of the component can also be corrected.

The friction blocks 9 are part of a coarse rotational device 11 and are connected to the latter via piezoelectric drive elements 12, which adjust the friction blocks 9 in the direction of the slewing ring 7.

Instead of the coarse rotational device 11 with the friction blocks 9, a coarse rotational station (13), indicated by dash-dotted lines, may be arranged on the stator at a holding station of the grippers 5, which is designed in the same way as the fine rotational station 10.

1. An insertion head (1) comprising at least one rotational device (for example 10) for electric components (6), the turret-like insertion head (1) having a stator (2) and a rotor (3), on which a multiplicity of circularly distributed grippers (5) are mounted independently rotatably about a placement axis, the insertion head having an optical measuring device (for example 8) for detecting the position of the components (6) held on the grippers (5), it being possible after the optical measurement for the components to be rotated by a fine rotational device (10) precisely into the required placement position, characterized in that before the measurement the components can be rotated by means of a coarse rotational device (11) into a position approximate to the placement position.

2. The insertion head as claimed in claim 1, characterized in that the rotor (3) can be rotated step by step with respect to the stator (2), in that the the optical measuring device is designed as a measuring station (8) and in that the fine rotational device (10) is designed as a fine rotational station (10) anchored on the stator.

3. The insertion head as claimed in claim 2, characterized in that the coarse rotational device anchored on the stator is designed as a coarse rotational station (13) assigned to a holding station of the grippers (5).

4. The insertion head as claimed in claim 3, the gripper (5) having a slewing ring (7) which can be peripherally brought into frictional engagement with at least one frictional surface (14) of the rotational device (for example 10, 11), it being possible for the frictional surface (14) to be placed in the radial direction onto the slewing ring (7) and it being possible for the gripper (5) to be rotated by a tangential relative movement between the rotational device (for example 10, 11) and the slewing ring (7), characterized in that the stationary frictional surface (14) of the coarse rotational device (11) extends along the path of movement of the gripper (5), which can be rotated together with the rotor (3), and in that the rolling section on the frictional surface (14) can be changed by the controlled infeed of the frictional surface (14) onto the slewing ring (7).

5. The insertion head as claimed in claim 4, characterized in that the coarse rotational device (11) makes possible a rotational adjustment of the gripper (5) in coarse basic steps.

6. The device as claimed in claim 4 or 5, characterized in that the frictional surface (14) is formed on a radially adjustable friction block (9) anchored on the stator.

7. The device as claimed in claim 6, characterized in that the segmented frictional surface (14) is formed by a plurality of individually adjustable friction blocks (9), the friction length of which corresponds to the angle of rotation of a basic step.

8. The device as claimed in claim 6 or 7, characterized in that the frictional surfaces (14) are shorter than the distance between two of the slewing rings (7) adjacent to one another.
